(19) United States
(12) Patent Application Publication
(10) Pub. No.: US 2025/0079219 A1
(43) Pub. Date: Mar. 6, 2025

(54) SILICON WAFER TRANSFER AUXILIARY DEVICE AND SLICING MACHINE USING SILICON WAFER TRANSFER AUXILIARY DEVICE

(71) Applicant: TCL ZHONGHUAN RENEWABLE ENERGY TECHNOLOGY CO., LTD., Tianjin (CN)

(72) Inventors: Lihui JIN, Tianjin (CN); Hua YANG, Tianjin (CN); Zhigao REN, Tianjin (CN); Haodong GUO, Tianjin (CN); Chuanling AI, Tianjin (CN); Dawei WANG, Tianjin (CN); Zhijun WU, Tianjin (CN); Hongxia CEN, Tianjin (CN); Chen WEI, Tianjin (CN)

(73) Assignee: TCL ZHONGHUAN RENEWABLE ENERGY TECHNOLOGY CO., LTD., Tianjin (CN)

(21) Appl. No.: 18/553,526

(22) PCT Filed: Jul. 18, 2023
(86) PCT No.: PCT/CN2023/107808

§ 371 Date: Sep. 29, 2023

(30) Foreign Application Priority Data
Jun. 9, 2022 (CN) 202221431083.6

(51) Int. Cl. H01L 21/677

(52) U.S. Cl. CPC H01L 21/67784

(57) ABSTRACT

A silicon wafer transfer auxiliary device includes blowpipes disposed on a side of a sorting wheel. Nozzles of the blowpipes are inclined towards the side of the sorting wheel. The blowpipes are capable of spraying liquid or gas towards a silicon wafer during transfer to increase an adsorption force between the silicon wafer and the sorting wheel and to successfully complete a turning of the silicon wafer from a vertical direction to a side close to the sorting wheel.

### CROSS-REFERENCE TO RELATED APPLICATION

This application claims priority to and the benefit of Chinese Patent Application No. 202221431083.6, filed in the China National Intellectual Property Administration on Jun. 9, 2022, the disclosure of which is hereby incorporated by reference in its entirety.

### FIELD OF INVENTION

The present application relates to the field of silicon chip sorting equipment technologies, and more particularly to a silicon wafer transfer auxiliary device and a slicing machine using the silicon wafer transfer auxiliary device.

### BACKGROUND OF INVENTION

In the existing vertical slicing machine, silicon wafers are easy to rewind on a sorting wheel, an adsorption force is weak, and occasionally a phenomenon of falling chips may occur, resulting in a fragmentation of the silicon wafers and affecting a quality of slicing. Further, space between the sorting wheel and a water tank is narrow and difficult to operate.

### SUMMARY OF INVENTION

The present application provides a silicon wafer transfer auxiliary device and a slicing machine using the transfer auxiliary device. How to install a transfer auxiliary device in a limited space to solve the technical problem of wafer rewinding when silicon wafers are sliced, so as to improve an adsorption force of silicon wafers absorbed by a sorting wheel, improve an efficiency of slicing, and ensure a quality of silicon wafer sorting.

In order to solve at least one of the above-mentioned technical problems, the technical solution adopted in the present application is as follows.

A silicon wafer transfer auxiliary device includes blowpipes disposed on a side of a sorting wheel, nozzles of the blowpipes are inclined towards the side of the sorting wheel; the blowpipes are capable of spraying liquid or gas towards a silicon wafer during transfer to increase an adsorption force between the silicon wafer and the sorting wheel and to successfully complete a turning of the silicon wafer from a vertical direction to a side close to the sorting wheel.

In one of embodiments of the present application, the blowpipes are all configured on a frame set across a width direction of the sorting wheel and are located on a side of the frame set away from the sorting wheel.

In one of embodiments of the present application, the nozzles of the blowpipes are configured to spray toward a surface of the silicon wafer on a side away from the sorting wheel.

In one of embodiments of the present application, the nozzles of all the blowpipes are disposed in a same direction.

In one of embodiments of the present application, a number of the blowpipes is at least two, and the blowpipes are disposed along a width direction of the silicon wafer or/and perpendicular to the width direction of the silicon wafer.

In one of embodiments of the present application, a central width of two outermost blowpipes in a same row is not greater than ¾ of a width of the silicon wafer and not less than ½ of the width of the silicon wafer.

In one of embodiments of the present application, the frame set comprises a cross bar and a side plate fixed on the cross bar; the cross bar is detachably connected with the side plate.

In one of embodiments of the present application, both ends of the cross bar are respectively fixed on a frame placed outside the sorting wheel.

In one of embodiments of the present application, the side plate is vertically disposed and configured as a plate structure with a narrow top and a wide bottom.

In one of embodiments of the present application, the blowpipes are configured on a side of the side plate away from the sorting wheel and is located below the cross bar.

A slicing machine uses the above silicon wafer transfer auxiliary device in any one of embodiments.

A silicon wafer transfer auxiliary device and a slicing machine using the transfer auxiliary device in the present application have simple structures and are convenient for fixing as a whole. They can directly spray liquid or blow air on a side of a vertical silicon wafer to be absorbed, so as to increase an adsorption force of the silicon wafer being adsorbed by the sorting wheel, improve an efficiency of slicing, and ensure a quality of silicon wafer sorting.

### DESCRIPTION OF DRAWINGS

FIG. 1 is a perspective view of a silicon wafer transfer auxiliary device according to an embodiment of the present invention.

FIG. 2 is a side view of the cooperation between the transfer auxiliary device and the silicon wafer according to an embodiment of the present invention.

FIG. 3 is a schematic top view of a matching position of a blowpipe and a silicon wafer according to an embodiment of the present invention.

FIG. 4 is a schematic top view of a matching position of a blowpipe and a silicon wafer in another embodiment of the present invention.

FIG. 5 is a schematic top view of a matching position of a blowpipe and a silicon wafer in another embodiment of the present invention.

FIG. 6 is a schematic structural view of a side plate of an embodiment of the present invention.

In the drawings:

| | | |
|---|---|---|
| 10: Blowpipe | 20: Frame set | 21: Cross bar |
| 22: Side plate | 30: Sorting wheel | 40: Silicon wafer |

### DETAILED DESCRIPTION OF PREFERRED EMBODIMENTS

The present application will be described in detail below in conjunction with the accompanying drawings and specific embodiments.

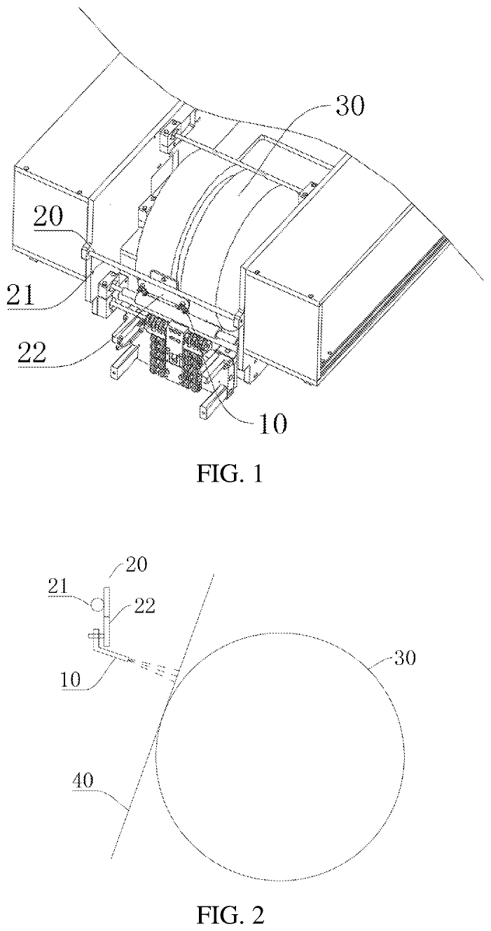

This embodiment proposes a silicon wafer transfer auxiliary device, as shown in FIG. 1, which includes several blowpipes 10 disposed on a side of a sorting wheel 30 and a frame set 20 configured to fix the blowpipes 10. All the blowpipes 10 are erected on the frame set 20 above a cleaning tank (figure omitted), and nozzles of all the blowpipes 10 are inclined towards a side of the sorting wheel. The blowpipes 10 can spray liquid or gas from the silicon wafer 40 towards the silicon wafer during transfer, so as to increase an adsorption force between the silicon wafer 40 and the sorting wheel 30, successfully complete the turning of the silicon wafer from the vertical direction to the side close to the side of the sorting wheel 30, and the rewinding of the silicon wafer 40 can be prevented. The cooperation between the blowpipes 10 and the frame set 20 is not only simple in assembly, but also simple in structure. It is especially suitable for such a place where the space is limited, and the direction of the liquid flow or air flow of the blowpipe 10 can be adjusted by itself. Based on the position of the silicon wafer 40, liquid is sprayed or blown toward the plane of the silicon wafer 40 adsorbed on the sorting wheel 30, so as to provide a forward spray or blow force to the silicon wafer 40. This makes the silicon wafer 40 fit better with the sorting wheel 30, prevents the silicon wafer 40 from rewinding or slipping, so as to ensure the sorting quality and sorting efficiency of the silicon wafer 40.

In one embodiment of the present application, all blowpipes 10 are fixed on the frame set 20 disposed across the width direction of the sorting wheel 30 and are located on the side of the frame set 20 away from the sorting wheel 30. This is not only convenient for adjusting the position of the nozzle of the blowpipe 10, but also facilitates the installation of the blowpipe 10, and there is more room for adjustment.

In one embodiment of the present application, as shown in FIG. 2, the nozzles of the blowpipes 10 are all inclined toward the surface of the silicon wafer 40 away from the side of the sorting wheel 30 to spray and form a certain angle with the surface of the silicon wafer. The liquid flow or gas flow can be directly perpendicular to the surface of the silicon wafer 40 or form an acute angle or an obtuse angle with the surface of the silicon wafer 40. However, no matter what the angle between the liquid flow or air flow and the silicon wafer 40 is, the included angles are all directed above the tangent line between the silicon wafer 40 and the sorting wheel 30. That is to say, the silicon wafer 40 is tilted toward the side of the sorting wheel 30 from the vertically placed structure. When the sorting wheel 30 is connected circumscribed to the surface of the silicon wafer 40, the nozzle of the blowpipe 10 may spray liquid or air towards the upper section of the silicon wafer 40. During the sorting process, the silicon wafers 40 are gradually attached to the sorting wheel 30 with a circular arc surface structure obliquely forward from the vertical standing state. After the silicon wafer 40 contacts with the sorting wheel 30, it is in an oblique upward state. After the silicon wafer 40 contacts with the sorting wheel 30, the nozzle of the blowpipe 10 is set toward the obliquely upward plane on the surface of the silicon chip 40, to give the silicon wafer 40 an upward thrust. This makes the silicon wafer 40 flip clockwise along the sorting wheel 30 for angle transfer, so that the sorting wheel 30 drives the silicon wafer 40 out of the cleaning tank, so that it can be smoothly attached to the sorting wheel 30 and avoids downward rewinding or swipe.

In one of the embodiments of the present application, the nozzles of all the blowpipes 10 are set in the same direction, so as to avoid blowing force in different directions to the silicon wafer 40, so that the silicon wafer 40 can obtain a uniform blowing force and ensure the stability of its fragmentation.

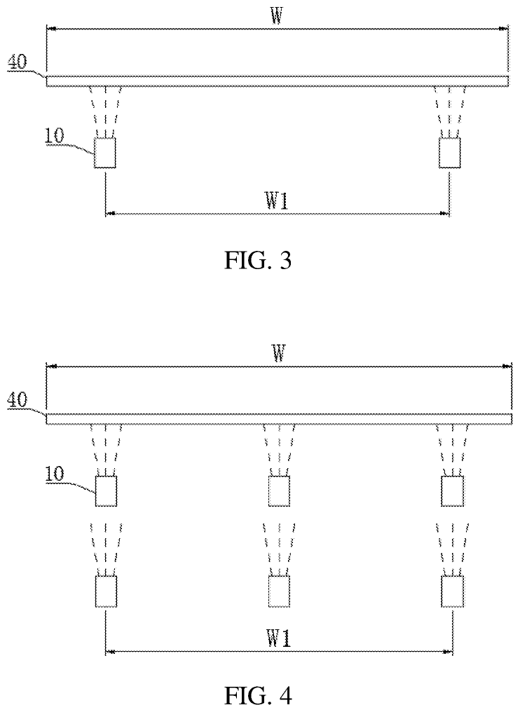

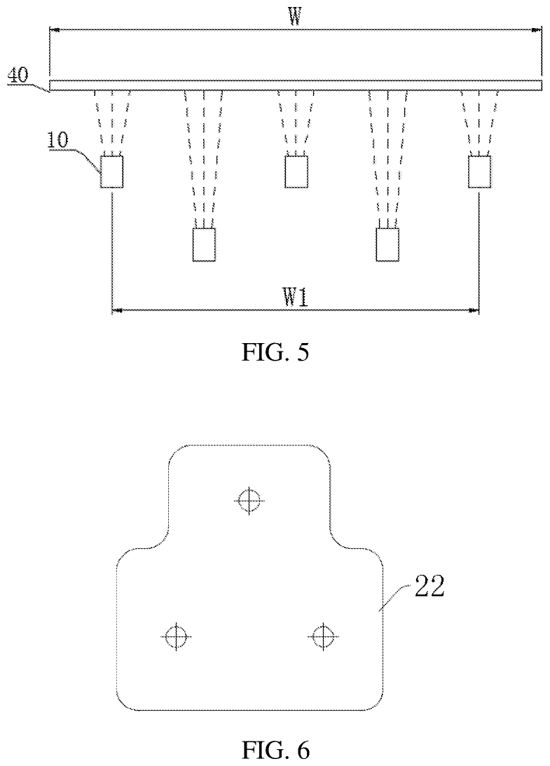

In one of the embodiments of the present application, the number of blowpipes 10 is at least two, which can be disposed at intervals along the width direction of the silicon wafer, disposed along the width direction perpendicular to the silicon wafer 40, disposed along the width direction of the silicon wafer 40, or disposed both along the width direction of the silicon wafer 40 and along the direction perpendicular to the width of the silicon wafer 40. Specifically, as shown in FIG. 3, two blowpipes 10 are provided with the same row of gaps and are disposed symmetrically along the center line of the silicon wafer 40. As shown in FIG. 4, there are two rows of blowpipes 10, and the number of each row of blowpipes 10 is three. The two peripheral blowpipes 10 of the same row are disposed symmetrically corresponding to the middle position of the blowpipes 10. In addition, the two blowpipes 10 vertically disposed in each of the two rows are disposed coaxially and dislocated up and down (the side view is omitted), and all spray toward one side of the silicon wafer 40. As shown in FIG. 5, two rows of blowpipes 10 are provided, and the quantity of the two rows of blowpipes 10 is not the same, the two rows of blowpipes 10 are staggered and spaced apart along the width direction of the silicon wafer 40, and both blow to the surface of the silicon wafer 40 to inject liquid or air flow. Because a single silicon wafer 40 is thin, it is not easy to withstand excessive blowing force, and considering the burden of the entire transfer auxiliary device, preferably, the number of blowpipes 10 is two. The two blowpipes 10 are disposed symmetrically with respect to the centerline of the sorting wheel 30, and under the condition of ensuring that their blowing force to the silicon wafer 40 is balanced, the overall blowing force is reduced to the greatest extent.

Further, the nozzle of the blowpipe 10 can be circular or flat, and there is no specific limitation here, as long as it can ensure continuous and uniform air outlet, all are within the protection scope of this case.

In one of the embodiments of the present application, the central width W1 of the two outermost blowpipes 10 in the same row is not greater than ¾ of the width W of the silicon wafer 40 and is not less than ½ of the width W of the silicon wafer 40, as shown in FIG. 3 to FIG. 5. This is because, if the central width W of the two outermost blowpipes 10 in the same row is greater than ¾ of the width W of the silicon wafer 40, the force on both sides of the silicon wafer 40 will be greater. Since the stress on both sides of the silicon wafer 40 is relatively concentrated, it is prone to breakage, the area where the silicon wafer 40 is extremely fragile should be avoided. If the central width W1 of the two outermost blowpipes 10 in the same row is less than ½ of the width W of the silicon wafer 40, then all the blowing force is concentrated on the central axis position of the silicon wafer 40, which is not conducive to the lamination of the silicon wafer 40 as a whole and the sorting wheel 30, and the stress is unbalanced.

The two blowpipes 10 share the same gas pipe connection to ensure the consistency of the discharge liquid flow or air flow from the blowpipe 10.

In one embodiment of the present application, the frame set 20 includes a cross bar 21 and a side plate 22 fixed on the cross bar 21. The cross bar 21 is detachably connected with the side plate 22, and the purpose is to facilitate the installation and adjustment of the position of the blowpipe 10. The side plate 22 is fixed at the middle position of the cross bar 21 and vertically arranged relative to the length direction of the cross bar 21. It is understood that an integrated fixed structure is also possible.

In one embodiment of the present application, the two ends of the cross bar 21 are respectively fixed on the frame outside the sorting wheel 30 and suspended in the air, which not only has a stable structure and saves the matching area, but also facilitates operation.

In one of the embodiments of the present application, the side plate 22 is vertically arranged on the cross bar 21, and the side plate 22 is configured as a board structure with a narrow top and a wide bottom. As shown in FIG. 6, all its corners are arc-shaped, and the narrow side of the side plate 22 is fixed on the cross bar 21, and its wide side is convenient for installing the blowpipe 10. This upper narrow and lower wide structure can reduce its weight on the basis of ensuring the fixed blowpipe 10, so as to increase the overall burden of the frame set 20.

In one embodiment of the present application, the blowpipe 10 is configured on the side of the side plate 22 away from the sorting wheel 30 and is located below the cross bar 21.

A slicing machine adopts the above-mentioned transfer auxiliary device.

The silicon wafer transfer auxiliary device has a simple structure and is convenient for fixing as a whole. It can directly spray liquid or blow air on a side of a vertical silicon wafer to be absorbed, so as to increase an adsorption force of the silicon wafer being adsorbed by the sorting wheel, improve an efficiency of slicing, and ensure a quality of silicon wafer sorting.

The embodiments of the present application have been described in detail above. The content described is only a preferred embodiment of the present application and cannot be considered as limiting the implementation scope of the present application. All equal changes and improvements made according to the application scope of the present application should still belong to the scope covered by the patent of the present application.

What is claimed is:

1. A silicon wafer transfer auxiliary device, comprising:
a sorting wheel; and
blowpipes disposed on a side of the sorting wheel, wherein nozzles of the blowpipes are inclined towards the side of the sorting wheel, and the blowpipes are capable of spraying liquid or gas towards a silicon wafer during transfer to increase an adsorption force between the silicon wafer and the sorting wheel and to successfully complete a turning of the silicon wafer from a vertical direction to a side close to the sorting wheel.

2. The silicon wafer transfer auxiliary device according to claim 1, further comprising a frame set, wherein the blowpipes are all configured on the frame set across a width direction of the sorting wheel and are located on a side of the frame set away from the sorting wheel.

3. The silicon wafer transfer auxiliary device according to claim 2, wherein the nozzles of the blowpipes are configured to spray toward a surface of the silicon wafer on a side away from the sorting wheel.

4. The silicon wafer transfer auxiliary device according to claim 2, wherein the nozzles of all the blowpipes are disposed in a same direction.

5. The silicon wafer transfer auxiliary device according to claim 4, wherein a number of the blowpipes is at least two, and the blowpipes are disposed along a width direction of the silicon wafer or/and perpendicular to the width direction of the silicon wafer.

6. The silicon wafer transfer auxiliary device according to claim 5, wherein a central width of two outermost blowpipes in a same row is not greater than ¾ of a width of the silicon wafer and not less than ½ of the width of the silicon wafer.

7. The silicon wafer transfer auxiliary device according to claim 2, wherein the frame set comprises a cross bar and a side plate fixed on the cross bar, and the cross bar is detachably connected with the side plate.

8. The silicon wafer transfer auxiliary device according to claim 7, wherein both ends of the cross bar are respectively fixed on a frame placed outside the sorting wheel.

9. The silicon wafer transfer auxiliary device according to claim 8, wherein the side plate is vertically disposed and configured as a plate structure with a narrow top and a wide bottom.

10. The silicon wafer transfer auxiliary device according to claim 8, wherein the blowpipes are configured on a side of the side plate away from the sorting wheel and is located below the cross bar.

11. A slicing machine, comprising:
a silicon wafer transfer auxiliary device comprising:
a sorting wheel; and
blowpipes disposed on a side of the sorting wheel, wherein nozzles of the blowpipes are inclined towards the side of the sorting wheel, and the blowpipes are capable of spraying liquid or gas towards a silicon wafer during transfer to increase an adsorption force between the silicon wafer and the sorting wheel and to successfully complete a turning of the silicon wafer from a vertical direction to a side close to the sorting wheel.

12. The slicing machine according to claim 11, further comprising a frame set, wherein the blowpipes are all configured on the frame set across a width direction of the sorting wheel and are located on a side of the frame set away from the sorting wheel.

13. The slicing machine according to claim 12, wherein the nozzles of the blowpipes are configured to spray toward a surface of the silicon wafer on a side away from the sorting wheel.

14. The slicing machine according to claim 12, wherein the nozzles of all the blowpipes are disposed in a same direction.

15. The slicing machine according to claim 14, wherein a number of the blowpipes is at least two, and the blowpipes are disposed along a width direction of the silicon wafer or/and perpendicular to the width direction of the silicon wafer.

16. The slicing machine according to claim 15, wherein a central width of two outermost blowpipes in a same row is not greater than ¾ of a width of the silicon wafer and not less than ½ of the width of the silicon wafer.

17. The slicing machine according to claim 12, wherein the frame set comprises a cross bar and a side plate fixed on the cross bar, and the cross bar is detachably connected with the side plate.

18. The slicing machine according to claim 17, wherein both ends of the cross bar are respectively fixed on a frame placed outside the sorting wheel.

19. The slicing machine according to claim 18, wherein the side plate is vertically disposed and configured as a plate structure with a narrow top and a wide bottom.

20. The slicing machine according to claim 18, wherein the blowpipes are configured on a side of the side plate away from the sorting wheel and is located below the cross bar.
